(19) United States
(12) Patent Application Publication
(10) Pub. No.: US 2012/0255592 A1
(43) Pub. Date: Oct. 11, 2012

(54) PHOTOVOLTAIC PANEL AND MANUFACTURING METHOD THEREOF

(75) Inventors: Kai-Sheng Chang, Miaoli County (TW); Chen-Chan Wang, Miaoli County (TW); Tzu-Chun Chen, Miaoli County (TW); Chia-Hung Wu, Miaoli County (TW); Hung-Ming Lin, Miaoli County (TW); Ching-Tang Tsai, Miaoli County (TW); Tien-Szu Chen, Miaoli County (TW); Kuei-Wu Huang, Miaoli County (TW)

(73) Assignee: GINTECH ENERGY CORPORATION, Miaoli County (TW)

(21) Appl. No.: 13/191,242

(22) Filed: Jul. 26, 2011

(30) Foreign Application Priority Data
Apr. 8, 2011 (TW) 100112246

(51) Int. Cl. H01L 31/05; H01L 31/0224

(52) U.S. Cl. 136/244; 438/73; 257/E31.124

(57) ABSTRACT

A photovoltaic panel includes a photovoltaic array, an electrically conductive busbar, a plurality of electrically conductive fingers and an electrically conductive ribbon. The electrically conductive busbar is disposed on the photovoltaic array and having a plurality of connection ribs. The electrically conductive fingers are disposed on the photovoltaic array and connected with the connection ribs respectively. The electrically conductive ribbon is soldered on the electrically conductive busbar, wherein a gap is formed between each electrically conductive finger and the electrically conductive ribbon.

### RELATED APPLICATIONS

This application claims priority to Taiwan Application Serial Number 100112246, filed Apr. 8, 2011 which is herein incorporated by reference.

### BACKGROUND

1. Field of Invention

The present invention relates to a photovoltaic device. More particularly, the present invention relates to a photovoltaic panel and manufacturing method thereof.

2. Description of Related Art

In recent years, awareness of ecological problems has been raised worldwide. Among other things, the global warming resulting from CO₂ emission is a serious concern, and clean energy has been increasingly desired. In such a circumstance, a solar cell shows great promise to serve as a source of clean energy in terms of its safety and operability.

In addition to the photoelectric conversion layer for converting light into electricity, the solar panel still needs a plurality of electrically conductive channels to collect electricity and output for external use or storing in a battery.

In order to reduce less energy consumption during electricity transporting, a contact resistance at a joint interface should be as low as possible, e.g. solder joint should be well soldered to enhance its bonding strength, so as to enhance a solar panel's operation efficiency and prolong its operation life.

### SUMMARY

It is therefore an objective of the present invention to provide an improved method for manufacturing electrically conductive channels on a photovoltaic panel.

In accordance with the foregoing and other objectives of the present invention, a photovoltaic panel includes a photovoltaic array, an electrically conductive busbar, a plurality of electrically conductive fingers and an electrically conductive ribbon. The electrically conductive busbar is disposed on the photovoltaic array and having a plurality of connection ribs. The electrically conductive fingers are disposed on the photovoltaic array and connected with the connection ribs respectively. The electrically conductive ribbon is soldered on the electrically conductive busbar, wherein a gap is formed between each electrically conductive finger and the electrically conductive ribbon.

According to an embodiment disclosed herein, the gap is greater than about 100 μm.

According to another embodiment disclosed herein, the gap ranges from 100 μm to 500 μm.

According to another embodiment disclosed herein, an elongate axis of the electrically conductive busbar is substantially perpendicular to an elongate axis of the electrically conductive finger.

According to another embodiment disclosed herein, a thickness of each electrically conductive finger is greater than a thickness of each connection rib.

According to another embodiment disclosed herein, a width of each electrically conductive finger is smaller than a width of each connection rib.

In accordance with the foregoing and other objectives of the present invention, a photovoltaic panel includes a photovoltaic array, a method for manufacturing electrically conductive channels on a photovoltaic panel includes the steps of (a) forming an electrically conductive busbar on a photovoltaic array of a photovoltaic panel, wherein the electrically conductive busbar has a plurality of connection ribs; (b) forming a plurality of electrically conductive fingers on the photovoltaic array; and (c) soldering an electrically conductive ribbon on the electrically conductive busbar and forming a gap between each electrically conductive finger and the electrically conductive ribbon.

According to an embodiment disclosed herein, the step (a) is executed before the step (b) and the electrically conductive fingers are connected with the connection ribs respectively.

According to another embodiment disclosed herein, the step (b) is executed before the step (a) and the electrically conductive fingers are connected with the connection ribs respectively.

According to another embodiment disclosed herein, the step (a) and step (b) are executed simultaneously, and the step (b) is executed twice such that a thickness of each electrically conductive finger is greater than a thickness of each connection rib.

According to another embodiment disclosed herein, the gap is greater than about 100 μm.

According to another embodiment disclosed herein, the gap ranges from about 100 μm to about 500 μm.

According to another embodiment disclosed herein, an elongate axis of the electrically conductive busbar is substantially perpendicular to an elongate axis of the electrically conductive finger.

According to another embodiment disclosed herein, a thickness of each electrically conductive finger is greater than a thickness of each connection rib.

According to another embodiment disclosed herein, a width of each electrically conductive finger is smaller than a width of each connection rib.

Thus, the electrically conductive finger of the photovoltaic panel is formed to intentionally form a gap between the electrically conductive ribbon and each electrically conductive finger so as to insure that the electrically conductive finger would not form part of the soldering interface between the electrically conductive ribbon and electrically conductive busbar, thereby downgrading the strength and reliability of the soldering interface.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 illustrates a top view of a photovoltaic panel according to one preferred embodiment of this invention;

FIGS. 2A-2C illustrate thee steps for manufacturing electrically conductive channels on a photovoltaic panel according to a first embodiment of this invention;

FIGS. 3A-3C illustrate thee steps for manufacturing electrically conductive channels on a photovoltaic panel according to a second embodiment of this invention; and

FIGS. 4A-4C illustrate thee steps for manufacturing electrically conductive channels on a photovoltaic panel according to a third embodiment of this invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

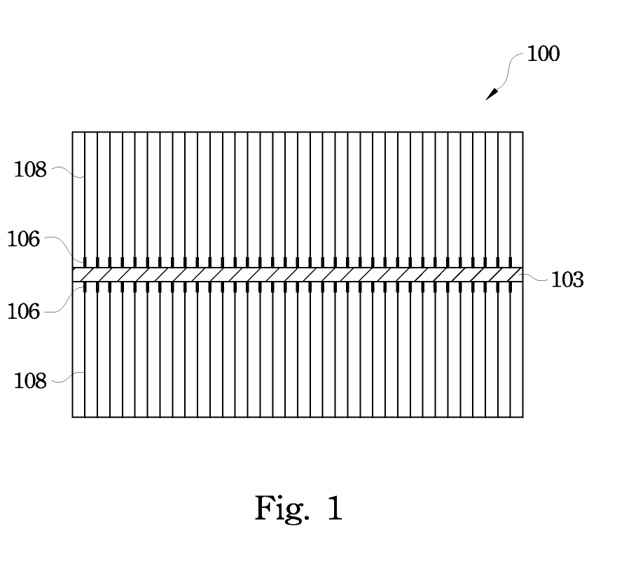

Referring to FIG. 1, which illustrates a top view of a photovoltaic panel according to one preferred embodiment of this invention. Various electrically conductive channels are manufactured on the photovoltaic panel 100 by screen printing. The electrical currents generated by the photovoltaic array are transferred by the electrically conductive finger 108 of smaller cross-section and collected by the electrically conductive channels 103 of larger cross-section so as to be output for external use or stored in a battery.

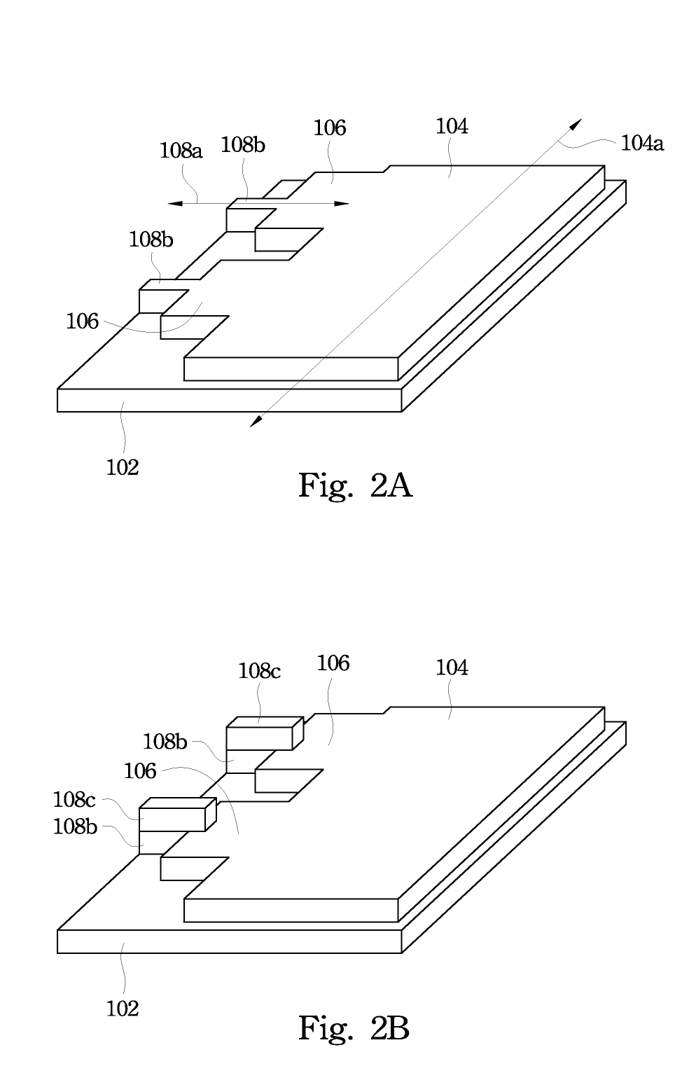

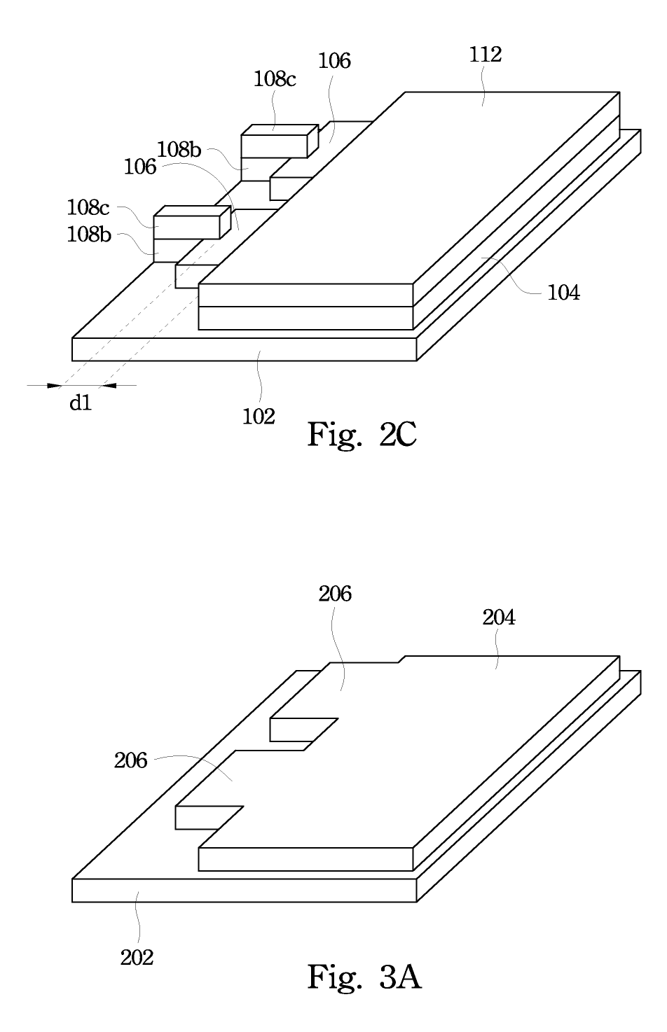

Referring to FIGS. 2A-2C, which illustrate thee steps for manufacturing electrically conductive channels on a photovoltaic panel according to a first embodiment of this invention. For clarity, only part of the electrically conductive fingers and the electrically conductive busbar are illustrated.

In FIG. 2A, a first screen printing is performed to print a conductive adhesive to form an electrically conductive busbar 104, a plurality of connection ribs 106 and a plurality of electrically conductive fingers 108b on a photovoltaic array 102 of the photovoltaic panel. The conductive adhesive can be, but not limited to, sliver or aluminum based adhesive. An elongate axis 104a of the electrically conductive busbar 104 is substantially perpendicular to an elongate axis 108a of the electrically conductive finger 108b.

In FIG. 2B, a second screen printing is performed to print conductive adhesive to form a plurality of electrically conductive finger 108c, which are respectively are on top of the electrically conductive fingers 108b so as to increase a thickness of each electrically conductive finger, thereby reducing an electrical resistance of each electrically conductive finger. Because the electrically conductive fingers 108b would prevent the light from entering the photovoltaic array 102, each electrically conductive finger is increased in its thickness instead of its width so as to impede light entering as less as possible. The connection ribs 106 are interconnected between the electrically conductive busbar 104 and the electrically conductive fingers 108b. Because a thickness of each connection rib 106 is smaller than a thickness of the electrically conductive finger stack (108b, 108c), a width of each connection rib 106 is thus broadened to maintain its lower electrical resistance. Another function of the connection rib 106 is used as an alignment mark for screen printing the electrically conductive finger 108c precisely.

In FIG. 2C, an electrically conductive ribbon 112 is soldered on the electrically conductive busbar 104 to form a complete conductive channel for the photovoltaic panel. In this embodiment, when each electrically conductive finger 108c is printed on part of the connection rib 106, and a gap d1 is intentionally formed between the electrically conductive ribbon 112 and each electrically conductive finger 108c. In this embodiment, the gap d1 is greater than 100 μm, and preferably ranges from about 100 μm to about 500 μm, but the gap d1 is determined according to a screen printing machine's fault tolerance.

The gap d1 is kept for enhancing the strength and reliability of the soldering interface between the electrically conductive ribbon 112 and electrically conductive busbar 104. When the electrically conductive finger 108c reaches the electrically conductive busbar 104 (e.g. the electrically conductive finger 108c is in contact with an upper surface of the electrically conductive busbar 104), the electrically conductive finger 108c may form part of the soldering interface between the electrically conductive ribbon 112 and electrically conductive busbar 104, thereby downgrading the strength and reliability of the soldering interface.

In this embodiment, the electrically conductive finger (108b, 108c) can be regarded as the electrically conductive finger 108 in FIG. 1 while the electrically conductive busbar 104 plus the electrically conductive ribbon 112 can be regarded as the electrically conductive channel 103 in FIG. 1.

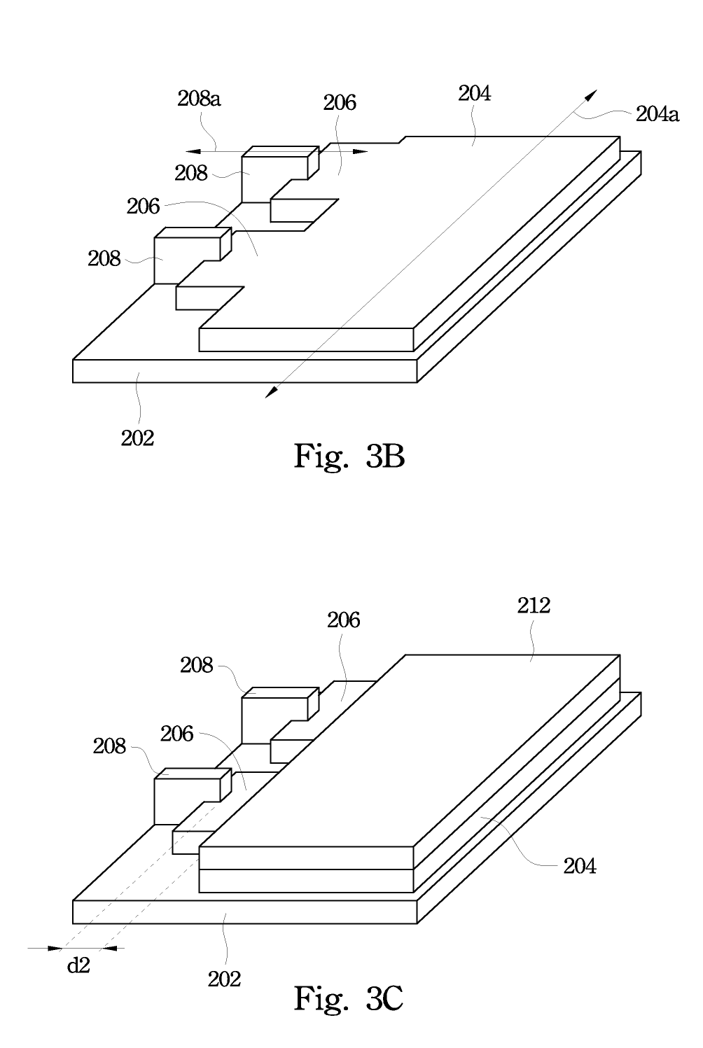

Referring to FIGS. 3A-3C, which illustrate thee steps for manufacturing electrically conductive channels on a photovoltaic panel according to a second embodiment of this invention. For clarity, only part of the electrically conductive fingers and the electrically conductive busbar are illustrated.

In FIG. 3A, a first screen printing is performed to print a conductive adhesive to form an electrically conductive busbar 204 and a plurality of connection ribs 206 on a photovoltaic array 202 of the photovoltaic panel. FIG. 3A is different from FIG. 2A in that the first screen printing does not print the electrically conductive fingers. The conductive adhesive can be, but not limited to, sliver or aluminum based adhesive.

In FIG. 3B, a second screen printing is performed to print a conductive adhesive to form a plurality of electrically conductive fingers 208 to connected with each connection rib 206. FIG. 3B is different from FIG. 2B in that each electrically conductive finger 208 is formed with its desired thickness by printing once instead printing twice. A thickness of each electrically conductive finger 208 is greater than a thickness of each connection rib 206 so as to lower its electrical resistance. Because the electrically conductive fingers 208 would prevent the light from entering the photovoltaic array 202, each electrically conductive finger 208 is increased in its thickness instead of its width so as to impede light entering as less as possible. The connection ribs 206 are interconnected between the electrically conductive busbar 204 and the electrically conductive fingers 208. Because a thickness of each connection rib 206 is smaller than a thickness of the electrically conductive finger 208, a width of each connection rib 206 is thus broadened to be larger than a width of each electrically conductive finger 208 to maintain its lower electrical resistance. Another function of the connection rib 206 is used as an alignment mark for screen printing the electrically conductive finger 208 precisely. An elongate axis 204a of the electrically conductive busbar 204 is substantially perpendicular to an elongate axis 208a of the electrically conductive finger 208.

In FIG. 3C, an electrically conductive ribbon 212 is soldered on the electrically conductive busbar 204 to form a complete conductive channel for the photovoltaic panel. In this embodiment, when each electrically conductive finger 208 is printed on part of the connection rib 206, and a gap d2 is intentionally formed between the electrically conductive ribbon 212 and each electrically conductive finger 208. In this embodiment, the gap d2 is greater than 100 μm, and preferably ranges from about 100 μm to about 500 μm, but the gap d2 is determined according to a screen printing machine's fault tolerance.

The gap d2 is kept for enhancing the strength and reliability of the soldering interface between the electrically conductive ribbon 212 and electrically conductive busbar 204. When the electrically conductive finger 208 reaches the electrically conductive busbar 204 (e.g. the electrically conductive finger 208 is in contact with an upper surface of the electrically conductive busbar 204), the electrically conductive finger 208 may form part of the soldering interface between the electrically conductive ribbon 212 and electrically conductive busbar 204, thereby downgrading the strength and reliability of the soldering interface.

In this embodiment, the electrically conductive finger 208 can be regarded as the electrically conductive finger 108 in FIG. 1 while the electrically conductive busbar 204 plus the electrically conductive ribbon 212 can be regarded as the electrically conductive channel 103 in FIG. 1.

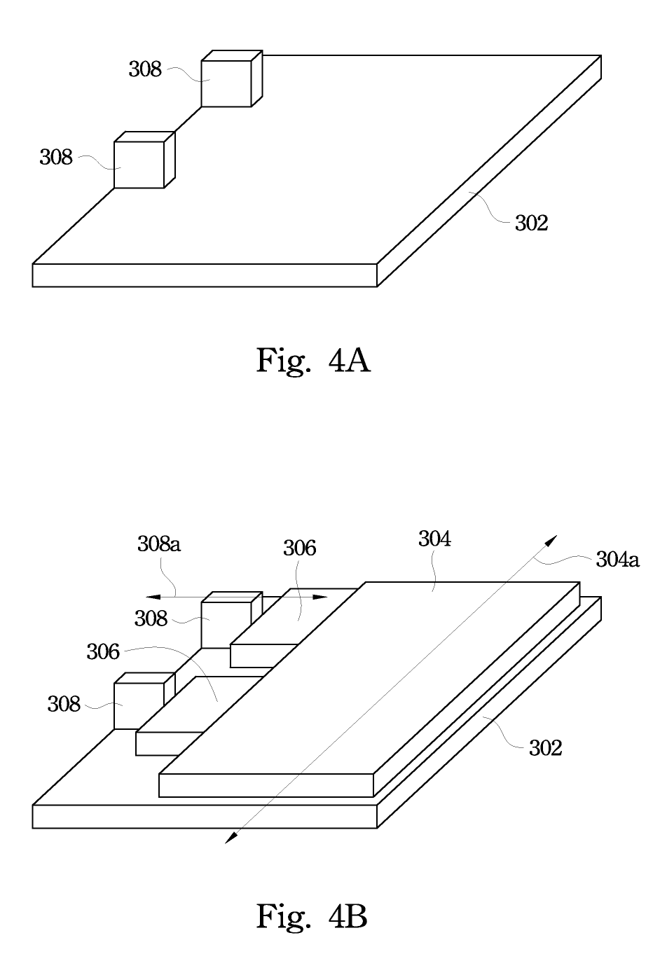

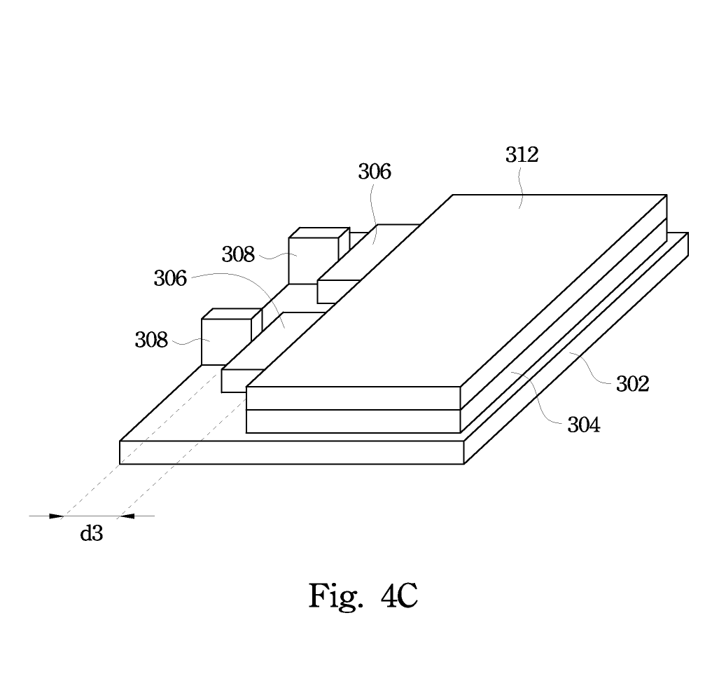

Referring to FIGS. 4A-4C, which illustrate thee steps for manufacturing electrically conductive channels on a photovoltaic panel according to a third embodiment of this invention. For clarity, only part of the electrically conductive fingers and the electrically conductive busbar are illustrated. The third embodiment is different from the first and second embodiment in that the electrically conductive finger is formed before forming the electrically conductive busbar and connection ribs.

In FIG. 4A, a first screen printing is performed to print a conductive adhesive to form a plurality of electrically conductive fingers 308 on a photovoltaic array 302 of the photovoltaic panel.

In FIG. 4B, a second screen printing is performed to print a conductive adhesive to form an electrically conductive busbar 304 and a plurality of connection ribs 306. A thickness of each electrically conductive finger 308 is greater than a thickness of each connection rib 306 so as to lower its electrical resistance. Because the electrically conductive fingers 308 would prevent the light from entering the photovoltaic array 302, each electrically conductive finger 308 is increased in its thickness instead of its width so as to impede light entering as less as possible. The connection ribs 306 are interconnected between the electrically conductive busbar 304 and the electrically conductive fingers 308. Because a thickness of each connection rib 306 is smaller than a thickness of the electrically conductive finger 308, a width of each connection rib 306 is thus broadened to be larger than a width of each electrically conductive finger 308 to maintain its lower electrical resistance. Besides, an elongate axis 304a of the electrically conductive busbar 304 is substantially perpendicular to an elongate axis 308a of the electrically conductive finger 308.

In FIG. 4C, an electrically conductive ribbon 312 is soldered on the electrically conductive busbar 304 to form a complete conductive channel for the photovoltaic panel. In this embodiment, when each electrically conductive finger 308 is printed on part of the connection rib 306, and a gap d3 is intentionally formed between the electrically conductive ribbon 312 and each electrically conductive finger 308. In this embodiment, the gap d3 is greater than 100 μm, and preferably ranges from about 100 μm to about 500 μm, but the gap d3 is determined according to a screen printing machine's fault tolerance.

The gap d3 is kept for enhancing the strength and reliability of the soldering interface between the electrically conductive ribbon 312 and electrically conductive busbar 304. When the electrically conductive finger 308 reaches the electrically conductive busbar 304 (e.g. in contact with an upper surface of the electrically conductive busbar 304), the electrically conductive finger 308 may form part of the soldering interface between the electrically conductive ribbon 312 and electrically conductive busbar 304, thereby downgrading the strength and reliability of the soldering interface.

In this embodiment, the electrically conductive finger 308 can be regarded as the electrically conductive finger 108 in FIG. 1 while the electrically conductive busbar 304 plus the electrically conductive ribbon 312 can be regarded as the electrically conductive channel 103 in FIG. 1.

According to the discussed embodiments, the electrically conductive finger of the photovoltaic panel is formed to intentionally form a gap between the electrically conductive ribbon and each electrically conductive finger so as to insure that the electrically conductive finger would not form part of the soldering interface between the electrically conductive ribbon and electrically conductive busbar, thereby downgrading the strength and reliability of the soldering interface.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A photovoltaic panel comprising:
a photovoltaic array;
an electrically conductive busbar disposed on the photovoltaic array and having a plurality of connection ribs;
a plurality of electrically conductive fingers disposed on the photovoltaic array and connected with the connection ribs respectively; and
an electrically conductive ribbon being soldered on the electrically conductive busbar, wherein a gap is formed between each electrically conductive finger and the electrically conductive ribbon.

2. The photovoltaic panel of claim 1, wherein the gap is greater than about 100 μm.

3. The photovoltaic panel of claim 1, wherein the gap ranges from 100 μm to 500 μm.

4. The photovoltaic panel of claim 1, wherein an elongate axis of the electrically conductive busbar is substantially perpendicular to an elongate axis of the electrically conductive finger.

5. The photovoltaic panel of claim 1, wherein a thickness of each electrically conductive finger is greater than a thickness of each connection rib.

6. The photovoltaic panel of claim 1, wherein a width of each electrically conductive finger is smaller than a width of each connection rib.

7. A method for manufacturing electrically conductive channels on a photovoltaic panel comprising:
(a) forming an electrically conductive busbar on a photovoltaic array of a photovoltaic panel, wherein the electrically conductive busbar has a plurality of connection ribs;
(b) forming a plurality of electrically conductive fingers on the photovoltaic array; and
(c) soldering an electrically conductive ribbon on the electrically conductive busbar and forming a gap between each electrically conductive finger and the electrically conductive ribbon.

8. The method of claim 7, wherein the step (a) is executed before the step (b) and the electrically conductive fingers are connected with the connection ribs respectively.

9. The method of claim 7, wherein the step (b) is executed before the step (a) and the electrically conductive fingers are connected with the connection ribs respectively.

10. The method of claim 7, wherein the step (a) and step (b) are executed simultaneously, and the step (b) is executed twice such that a thickness of each electrically conductive finger is greater than a thickness of each connection rib.

11. The method of claim 7, wherein the gap is greater than about 100 μm.

12. The method of claim 7, wherein the gap ranges from 100 μm to 500 μm.

13. The method of claim 7, wherein a thickness of each electrically conductive finger is greater than a thickness of each connection rib.

14. The method of claim 7, wherein a width of each electrically conductive finger is smaller than a width of each connection rib.

15. The method of claim 7, wherein an elongate axis of the electrically conductive busbar is substantially perpendicular to an elongate axis of the electrically conductive finger.
